(19) United States
(12) Patent Application Publication
(10) Pub. No.: US 2023/0073020 A1
(43) Pub. Date: Mar. 9, 2023

(54) HIGH POWER AND BROADBAND DISTRIBUTED CHOKE INDUCTOR FOR DISTRIBUTED POWER AMPLIFIERS

(71) Applicants: ASELSAN ELEKTRONIK SANAYI VE TICARET ANONIM SIRKETI, Ankara (TR); IHSAN DOGRAMACI BILKENT UNIVERSITESI, Ankara (TR)

(72) Inventors: Abdullah ATALAR, Ankara (TR); Ahmet DEGIRMENCI, Ankara (TR); Ahmet AKTUG, Ankara (TR); Cagdas BALLI, Ankara (TR)

(73) Assignees: ASELSAN ELEKTRONIK SANAYI VE TICARET ANONIM SIRKETI, Ankara (TR); IHSAN DOGRAMACI BILKENT UNIVERSITESI, Ankara (TR)

(21) Appl. No.: 17/903,075

(22) Filed: Sep. 6, 2022

(30) Foreign Application Priority Data
Sep. 7, 2021 (TR) 2021/014018

(51) Int. Cl. H03F 1/56; H03F 1/02; H03F 1/42; H03F 3/21; H03F 3/19

(52) U.S. Cl. CPC H03F 1/565; H03F 1/0205; H03F 1/42; H03F 3/21; H03F 3/19

(57) ABSTRACT

A broadband choke inductor is used in a bias circuit for broadband high-power distributed amplifiers.

CROSS REFERENCE TO THE RELATED APPLICATIONS

This application is based upon and claims priority to Turkish Patent Application No. 2021/014018, filed on Sep. 7, 2021, the entire contents of which are incorporated herein by reference.

### TECHNICAL FIELD

The invention relates to a choke inductor used in a bias circuit for broadband distributed high power amplifiers, enabling bandwidth enhancement.

### BACKGROUND

Today's broadband products use low gate length technologies. Some broadband products use structures with different transistor topologies (cascode, stack-fet). Low gate-length technologies are difficult to use and costly to manufacture. In order to use structures with different transistor topologies in related designs, models with high frequencies, high accuracy and different structures (common source, common gate) are required.

In distributed power amplifier designs, the bias circuit consisting of a choke inductor and decoupling capacitor is implemented on-chip. In designs targeting high power with high efficiency in broadband, on-chip bias circuit is preferred to reduce parasitic capacitances and losses. The inductor in the bias circuit has a direct effect on the performance and bandwidth of the circuit. The optimum value of the inductor is very important for broadband power amplifiers. Line width of the inductor should be wide enough to handle the peak drain current and at the same time it should have an inductance value that can block RF (Radio frequency) transmission at high frequency with low loss. The inductor value must have a high reactance at low frequency to prevent RF transmission sufficiently and a low shunt parasitic capacitor to decrease losses at high frequency.

Although today's technology allows for higher frequencies in terms of power and gain, a practically realized on-chip choke inductor can limit the performance of the power amplifier above 18 GHz due to a not very small shunt parasitic capacitance compared to a power amplifier that can operate above 18 GHz with the use of an ideal (lossless) bias circuit. Therefore, one of the factors directly affecting the performance of the power amplifier is this non-ideal inductor.

As a result of the research on the subject, application numbered as EP3195471B1 was found. This application relates to a broadband radio frequency power amplifier. However, the choke inductor structure used in the bias circuit cannot be found in the relevant application.

As a result, due to the negativities described above and the inadequacy of the existing solutions on the subject, it has become necessary to make a development in the relevant technical field.

### SUMMARY

The invention is inspired by the current situation and aims to solve the above mentioned problems.

The main aim of the invention is to reduce the shunt parasitic capacitors in bias circuits, and therefore to obtain broadband values.

Another aim of the invention is to reduce the resistive losses caused by the current flowing through the inductor.

Another aim of the invention is to increase the bandwidth without loss of performance.

Another aim of the invention is to reduce the effect of the choke inductor on the bandwidth in the bias circuit.

In order to fulfill the above-mentioned purposes, the invention is a bias circuit including at least one choke inductor, one end of which is connected to the drain terminal of at least one transistor and the other end of which is connected to the supply voltage and to ground via the decoupling capacitor, for the purpose of reducing shunt parasitic capacitors and losses of the inductor in broadband, high efficiency and high power targeted designs.

The structural and characteristic features and all the advantages of the invention will be more clearly understood from the following figures and the detailed description with reference to these figures, and therefore the evaluation should be made in consideration of these figures and the detailed description.

### BRIEF DESCRIPTION OF THE DRAWINGS

FIG. 1 is a view of the measurement configuration used in the performance evaluations of the inductor in the conventional bias circuit used in the inventive distributed power amplifier designs.

FIG. 2 is a view comparing the simulation and measurement results of the inductor (Lc) in the conventional bias circuit used in the inventive distributed power amplifier designs.

FIG. 3 is a view of the high frequency lumped element model of the inventive bias circuit inductor (Lc).

FIG. 4 is a view of the simulation result showing the transmission losses and resonant frequency when two inductors with the same inductance value at low frequency with wide and narrow transmission line width are used in the bias circuit.

FIG. 5 is a view of the simulation result showing the transmission losses and resonant frequency when the parasitic capacitors Cp1 and Co shown in the lumped element model of the inventive inductor are present and when they are eliminated.

FIG. 6 is a view of the schematic drawing of the distributed amplifier with discrete components, where the inventive distributed amplifier is used.

FIG. 7 is a view of the lumped element model of the inventive distributed inductor together with the lumped element model of the distributed amplifier.

FIG. 8 is a view of the configuration of the inventive distributed inductor in a distributed power amplifier.

### DESCRIPTION OF PART REFERENCES

1. Inductor (L_{c})

Cₛ, Cₒ, Cₛ₁, Cₛ₂, Cₚ₁, Cₚ₂, Cₚ₃: Capacitor

R₁, R₂, R_{g} : Resistance

L₁, L₂: Inductor

V_{DD} : Drain Voltage

V_{G}: Gate Voltage

### DETAILED DESCRIPTION OF THE EMBODIMENTS

In this detailed description, the preferred configurations of the inductor (1) in the bias circuit of the invention will be explained only for a better understanding of the subject matter.

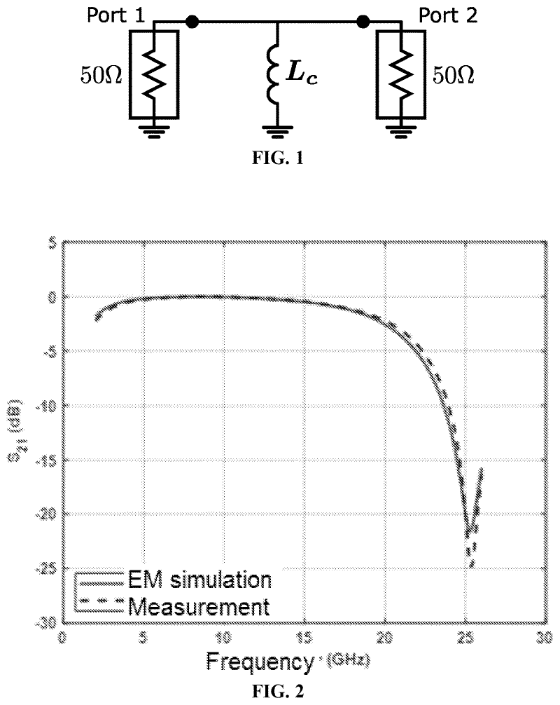

The bandwidth of an optimum inductor (1) that fulfills the criterion that the reactance value of the choke inductor (1) should be high at low frequency and the shunt parasitic capacitor (Cₚ₃) should be low in order to sufficiently prevent RF transmission is between 2-18 GHz. The simulation of a choke inductor (1) whose parameters are determined according to this optimum value is shown in FIG. 1.

Transmission lines having large width provide low resistance (R₁, R₂) but result in more shunt parasitic capacitors (Cₚ₁, Cₚ₂, Cₚ₃). These shunt parasitic capacitors (Cₚ₁, Cₚ₂, Cₚ₃) seriously affect the performance at high frequencies.

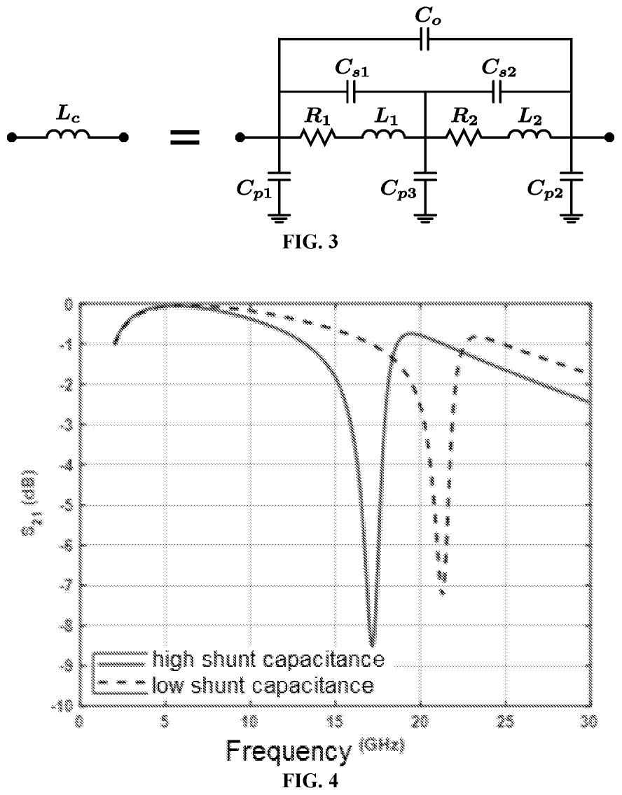

FIG. 4 is a view of the S21 simulation result of the 60 μm inductor (1) and 40 μm inductor (1) with the transmission line width subject to the invention. In addition, the lumped element model of the inductor (1) shown above is shown in FIG. 3. Here, the most important element determining the high frequency cut-off point is the Cp3 shunt capacitor (Cₚ₃). By reducing this parasitic capacitor (Cₚ₃), wider bandwidths can be achieved as can be seen in FIG. 4.

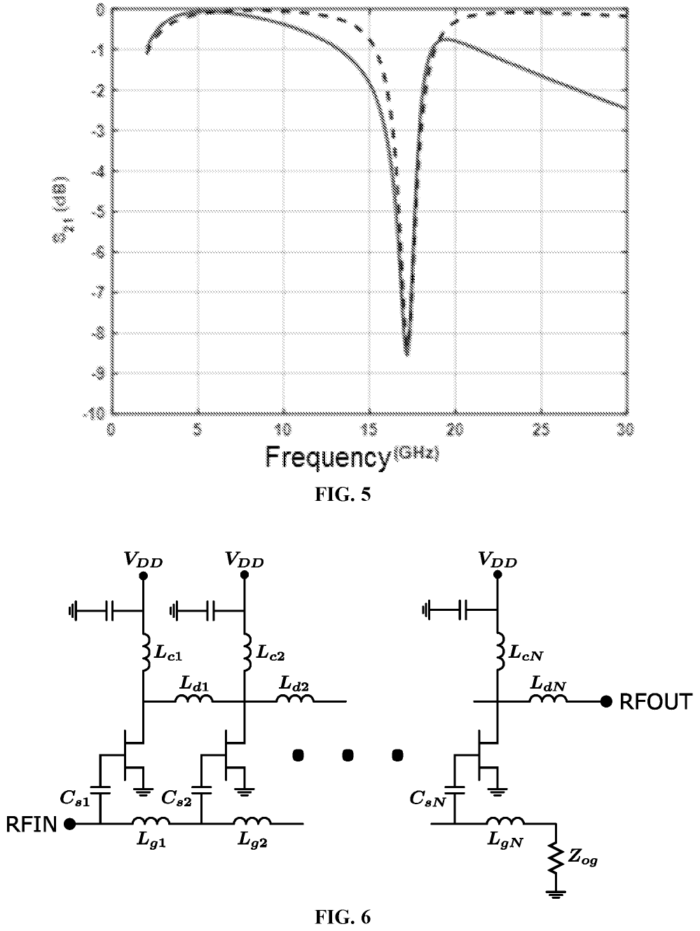

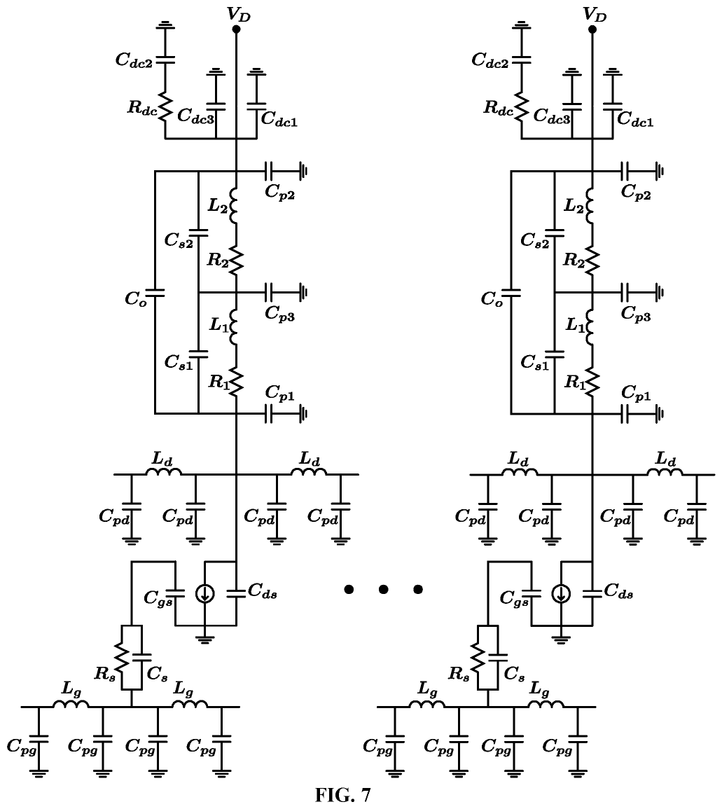

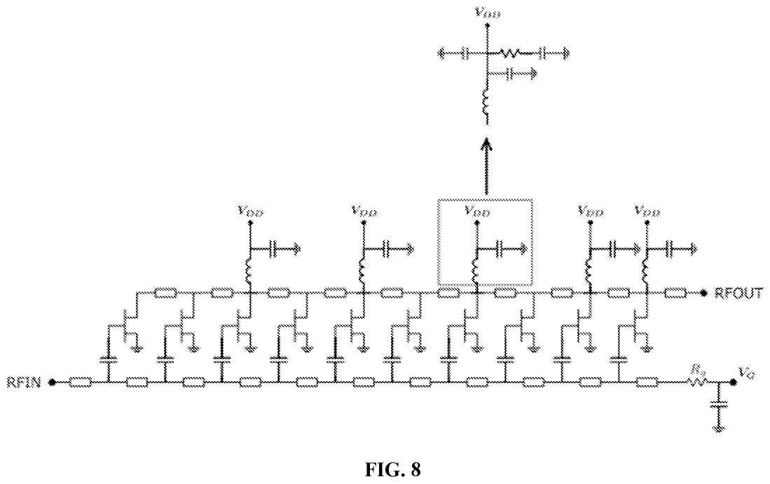

The most important parasitic capacitors (Cₚ₁, Cₒ) affecting the high frequency losses are Cp1 and Co. By reducing these parasitic capacitors (C_{g}), lower losses at high frequency can be achieved as can be seen in FIG. 5.

To increase the broadband value, the parasitic capacitor (Cp3) needs to be reduced. Reducing the width of the inductor (1) transmission lines reduces the parasitic capacitor (Cp3) but increases the losses. To reduce losses, more than one inductor (1) can be used in parallel. Since the current through each inductor (1) is reduced, the losses are also reduced.

In addition, when another small inductor (1) is placed between both choke inductors, this distributed structure eliminates the effect of the shunt parasitic capacitors (Cp1+Co). In the distributed amplifier structure, this small inductor (1) is already present between neighboring transistors and is used to neutralize the shunt capacitor of the transistor itself. By further increasing the value of this small inductor (1), the shunt parasitic capacitor of the bias choke inductor (1) can also be eliminated. The value of this small inductor (1) between two adjacent transistors is not equal in non-uniformly distributed power amplifiers (NDPA). In these amplifiers, the impedance seen by the first transistor can be made high and the impedance seen by the last transistor can be made low in order to achieve better power matching and increase efficiency. In this context, each inductor (1) value can be calculated separately according to the respective impedance and shunt parasitic capacitor values.

In one embodiment of the invention, five inductors (1) having a transmission line width of 15 μm are used in the bias circuit together with smaller inductors (1). Signal measurements are made in the bias circuit with five inductors (1) and it is observed that the bandwidth increases without any performance loss. One end of the inductors (1) used in the bias circuit is connected to the drain terminal of a transistor and the other end is connected to ground via the supply voltage (V_{DD}) and the decoupling capacitor. The bias circuit with five inductors (1) is connected to five different transistors.

What is claimed is:

1. A bias circuit used to reduce shunt parasitic capacitors and losses in broadband, high efficiency and high power designs, comprising:
at least two choke inductors on the bias circuit, wherein a first choke inductor of the at least two choke inductors is connected to a drain terminal of at least one transistor, and a second choke inductor of the at least two choke inductors is connected to a supply voltage (V_{DD}) and grounded via a decoupling capacitor.

2. The bias circuit according to claim 1, wherein each of the at least two choke inductors has a transmission line width of 15 μm.
